(19) United States
(12) Patent Application Publication
(10) Pub. No.: US 2025/0151219 A1
(43) Pub. Date: May 8, 2025

(54) MULTI-LAYER WET-DRY HARDCOATS INCLUDING DUAL-SIDED WET HARDCOATS FOR FLEXIBLE COVER LENS STRUCTURES, AND RELATED METHODS AND COATING SYSTEMS

(71) Applicant: Applied Materials, Inc., Santa Clara, CA (US)

(72) Inventors: Helinda NOMINANDA, San Jose, CA (US); Tae Kyung WON, San Jose, CA (US); Han NGUYEN, San Jose, CA (US); Seong Ho YOO, San Ramon, CA (US); Soo Young CHOI, Fremont, CA (US); Sung Hwan YOON, Incheon (KR); Yoon Duck HAN, Gyeonggi-do (KR); Chang Woo LEE, Seoul (KR); Kyung Whan PARK, Seoul (KR); Shi Youl SHIN, Seoul (KR)

(21) Appl. No.: 18/836,794

(22) PCT Filed: Mar. 24, 2023
(86) PCT No.: PCT/US2023/016261

§ 371 Date: Aug. 8, 2024

Related U.S. Application Data
(60) Provisional application No. 63/326,105, filed on Mar. 31, 2022.

(51) Int. Cl. H05K 5/03; G02B 1/14; G02B 1/18

(52) U.S. Cl. CPC H05K 5/03; G02B 1/14; G02B 1/18

(57) ABSTRACT

Embodiments of the present disclosure relate to flexible display devices, including dual-sided wet hardcoats for flexible cover lens structures, and related methods and coating systems. The flexible cover lens film has beneficial strength, elasticity. optical transmission, and anti-abrasion properties. In one or more embodiments. a cover lens structure for display devices includes a substrate layer including a first side and a second side. The cover lens structure includes a first wet hardcoat layer deposited on the first side of the substrate layer, and a second wet hardcoat layer deposited on the second side of the substrate layer. The cover lens structure includes one or more adhesion promotion layers formed above the second side. and a dry hardcoat layer formed above the second side.

### BACKGROUND

### Field

Embodiments of the present disclosure relate to flexible display devices, including dual-sided wet hardcoats for flexible cover lens structures, and related methods and coating systems.

### Description of the Related Art

Electronic devices often have displays such as liquid crystal displays (LCDs), organic light emitting-diode (OLED) displays, and quantum dot (QD) displays. Such displays can be fragile and sensitive to moisture, pressure, and/or particle contamination. Generally, display devices use several layers of optical devices to colorize, polarize, and shutter light from an illumination source. To prevent damage to the underlying film, a rigid display cover lens layer is mounted over the other layers to prevent damage to the underlying layers. The inclusion of the rigid display cover lens can add undesirable weight to an electronic device.

Cover lenses can also be hindered with respect to optical device performance (e.g., cover lenses can have limited light transmission and hazing), flexibility (e.g., cracking or plastically deforming at critical strains), and/or mechanical properties (such as hardness and impact resistance). For example, cover lenses can be susceptible to temperatures, and can exhibit increased particle migration and/or increased hazing. As an example, cover lenses can have oligomer migration. Replacing cover lenses can involve expertise, time, and great expense.

Therefore, there is a need for a flexible cover lens which has reduced hazing, mitigated oligomer migration, high hardness, high optical transmission, high elasticity, beneficial mechanical properties, and anti-abrasion properties.

### SUMMARY

Embodiments of the present disclosure relate to flexible display devices, including dual-sided wet hardcoats for flexible cover lens structures, and related methods and coating systems. The flexible cover lens film has beneficial strength, elasticity, optical transmission, and anti-abrasion properties.

In one or more embodiments, a cover lens structure for display devices includes a substrate layer including a first side and a second side. The cover lens structure includes a first wet hardcoat layer deposited on the first side of the substrate layer, and a second wet hardcoat layer deposited on the second side of the substrate layer. The cover lens structure includes one or more adhesion promotion layers formed above the second side, and a dry hardcoat layer formed above the second side.

In one or more embodiments, a method of forming a cover lens structure includes depositing a first hardcoat layer on a first side of a substrate layer using a first wet deposition process, and depositing a second hardcoat layer on a second side of the substrate layer using a second wet deposition process. The method includes depositing one or more adhesion promotion layers above the second side, and depositing a third hardcoat layer above the second side using a dry deposition process. The method includes depositing an anti-smudge layer above the second side, and disposing the cover lens structure to position the first hardcoat layer above a touch panel and a display structure of a display device.

In one or more embodiments, a coating system includes a first rotatable stem configured to receive a first storage reel, and a second rotatable stem configured to receive a second storage reel. The coating system includes a plurality of transfer rollers disposed along a transfer path between the first storage reel and the second storage reel, and a coating module interfacing with a first section of the transfer path. The coating module includes one or more of: a bar, a slot die, one or more comma rollers, a micro-gravure, a gravure, one or more cast nozzles, one or more cast rollers, or one or more spray nozzles. The coating system includes a curing module interfacing with a second section of the transfer path.

### BRIEF DESCRIPTION OF THE DRAWINGS

So that the manner in which the above recited features of the disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of scope, for the disclosure may admit to other equally effective implementations.

FIG. 1A is a schematic, cross-sectional view of a display device, according to one or more embodiments.

FIG. 1B is a schematic, cross-sectional view of a display device, according to one or more embodiments.

FIGS. 2A-2E are schematic cross-sectional views of a flexible cover lens film, respectively, according to one or more embodiments.

FIG. 3 is a schematic cross-sectional view of an exemplary embodiment of a flexible cover lens film including a double-stacked multi-layer hardcoat of the flexible cover lens film and a double-stacked first wet hardcoat layer, according to one or more embodiments.

FIG. 4A is a schematic plan view of a coating system during a first wet deposition process, according to one or more embodiments.

FIG. 4B is a schematic plan view of the coating system during a second wet deposition process, according to one or more embodiments.

FIG. 5 is a schematic block diagram view of a method of forming a cover lens structure, according to one or more embodiments.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Embodiments of the present disclosure relate to flexible display devices, including dual-sided wet hardcoats for flexible cover lens structures, and related methods and coating systems. The flexible cover lens film has beneficial strength, elasticity, optical transmission, and anti-abrasion properties. The flexible cover lens film has beneficial strength, elasticity, optical transmission, and anti-abrasion properties. The flexible cover lens film includes a hardcoat layer, a multi-layer hardcoat, and a substrate layer. The substrate layer can have a thickness of 2 μm to 100 μm, and the multi-layer hardcoat can have a thickness of 1 μm to 30 μm, such as 1 μm to 10 μm. The hardcoat layer is deposited using a first wet deposition process. The multi-layer hardcoat includes a second hardcoat layer deposited using a second wet deposition process, and a third hardcoat layer deposited using a dry deposition process, and one or more adhesion promotion layers. The substrate layer is dual-sided such that the hardcoat layer is disposed on a first side of the substrate layer and the second hardcoat layer is disposed on a second side of the substrate layer. In terms of optical properties, the flexible cover lens has a total transmission greater than 88%, a haze of about 1% or less, and a yellowness index of b*<1. By combining wet and dry deposition processes to form the multi-layer hardcoat, the cover lens film is both flexible and strong with hardness of 3H to 9H.

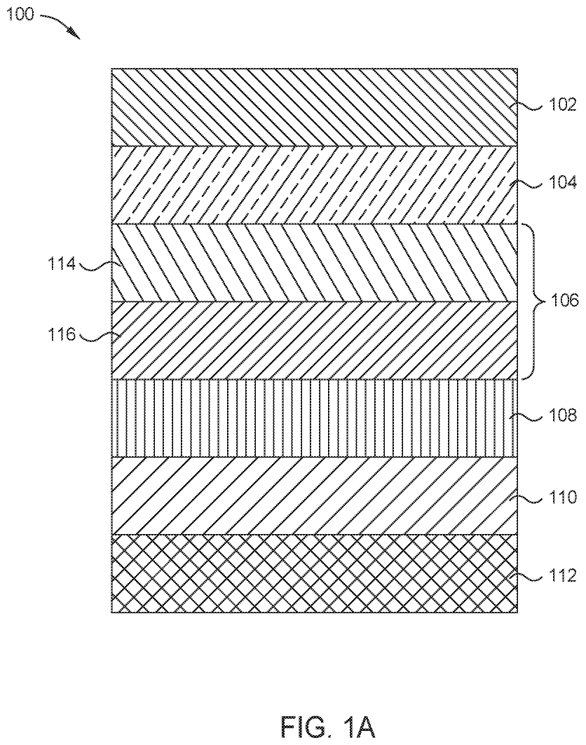

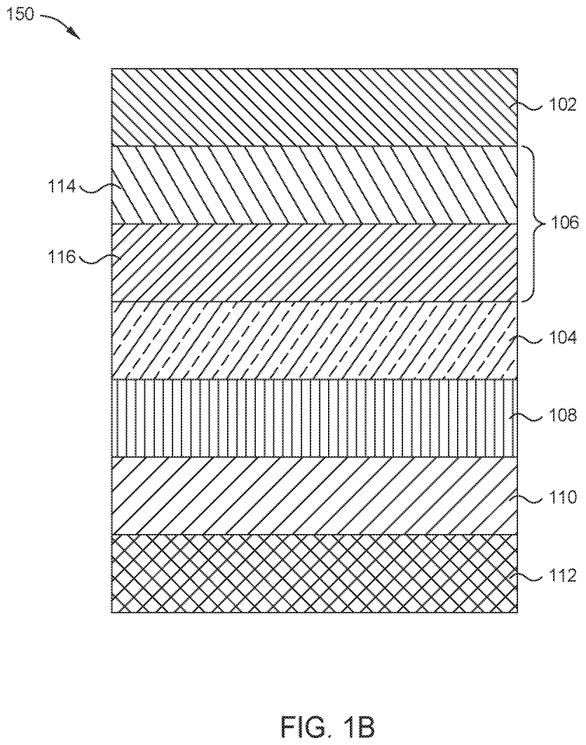

FIG. 1A is a schematic, cross-sectional view of a display device 100, according to one or more embodiments.

FIG. 1B is a schematic, cross-sectional view of a display device 150, according to one or more embodiments.

The display device 100 of FIG. 1A and the display device 150 of FIG. 1B include the same layers; however, the layers of each display device 100, 150 are in different orders. The display devices 100, 150 may be manufactured using roll-to-roll deposition, plasma enhanced chemical vapor deposition, chemical vapor deposition, physical vapor deposition, atomic layer deposition, photo-lithography, etching, and/or other such suitable manufacturing processes. Suitable manufacturing devices may be used from Applied Materials, Inc. of Santa Clara, CA. Other manufacturing devices may be used.

The display devices 100, 150 each include a cover lens film 102, a film layer 104, a touch panel 106, a display structure 108, a substrate 110, and a shielding layer 112. The cover lens film 102 may be bonded to a foldable glass substrate (e.g., ultra-thin glass). In the implementation of FIG. 1A, the film layer 104 is between the cover lens film 102 and the touch panel 106. In one or more embodiments, the film layer 104 is a multi-function film layer including a polarizer film. The film layer 104, such as polarizer film, is used to reduce unwanted reflections due to the reflective metal that makes up the electrode lines or metallic structures within the display device 100. The film layer 104 may include a quarter-wave retarder or a linear polarizer formed from flexible lens film, such as flexible lens film with a thickness of less than 0.2 mm. The cover lens film 102 may be bonded to the film layer 104 and the touch panel 106 with an optically clear adhesive (OCA). In one or more embodiments, the OCA is liquid-based adhesive utilized to bond the cover lens film 102 to the touch panel 106. In one or more embodiments, the OCA is an optically clear adhesive tape to bond the cover lens film 102 to the touch panel 106. The touch panel 106 includes a touch sensor IC board 114 and a touch sensor 116. In one implementation, the touch sensor IC board 114 is a flexible and metal base printed circuit board.

In the implementation of FIG. 1A, the display structure 108 is disposed between the touch panel 106 and substrate 110. In one or more embodiments, the display structure 108 is an organic light-emitting diode display. Other suitable display devices, such as light emitting diode displays or liquid crystal displays, which utilize a cover lens film, are contemplated herein. The display structure 108 may include a thin film encapsulation, organic emitting layer, driver IC board, and thin film transistor.

In FIG. 1B, the film layer 104 and the touch panel 106 may be layered on top of the display structure 108 such that the film layer 104 and the touch panel 106 are disposed between the display structure 108 and the cover lens film 102. In such an embodiment, the cover lens film 102 facilitates abrasion resistance and impact protection.

In one or more embodiments, the substrate 110 is made from a polymeric material, such as a polyimide material. The present disclosure contemplates that any flexible plastic substrate may be used for the substrate 110. For instance, the substrate 110 may includes a polyether ether ketone layer, transparent conductive polyester layer, polycarbonate, or any other polymer from the polyaryletherketone family. In the implementation of FIG. 1, the substrate 110 is adjacent the shielding layer 112. In one or more embodiments the substrate 110 is polyester terephthalate. In one embodiment, the shielding layer 112 is a copper foil. An additional layer such as an adhesion promoting layer may be deposited adjacent to the substrate 110 prior to any additional layers, such as the shielding layer 112.

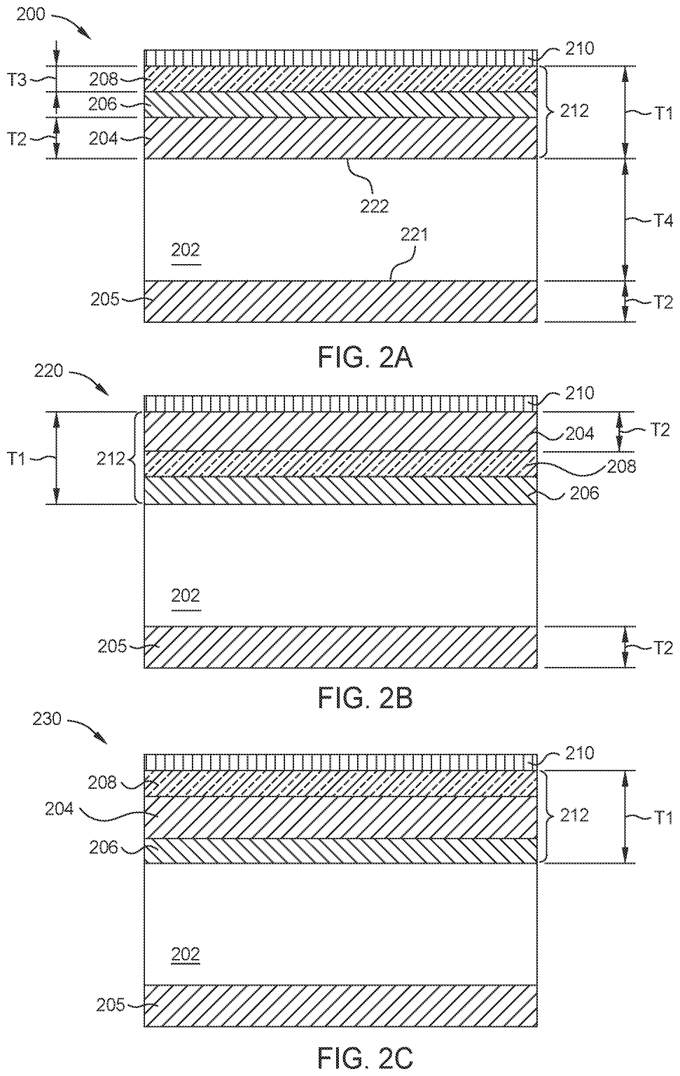

FIGS. 2A-2E are schematic cross-sectional views of a flexible cover lens film 200, 220, 230, 240, 250, respectively, according to one or more embodiments. Each of the flexible cover lens films 200, 220, 230, 240, 250 may be the cover lens film 102 of FIG. 1. The flexible cover lens films 200, 220, 230, 240, 250 may each be utilized in a display device, such as the display device 100 of FIG. 1A and/or the display device 150 of FIG. 1B. Each of the flexible cover lens films 200, 220, 230, 240, 250 includes a substrate layer 202, one or more adhesion promotion layers 206, a first wet hardcoat layer 205 deposited using a first wet deposition process, a second wet hardcoat layer 204 deposited using a second wet deposition process, and a dry hardcoat layer 208 deposited using a dry deposition process. A wet deposition process may include a solution including solvent and hardcoat chemistry deposited using a slot-die coating head, gravure coating head, or bar coating heads in roll to roll solution processing system. In one or more embodiments, the wet deposition process includes coating (e.g., spraying or rolling, for example) a hardcoat liquid (including hardcoat chemistry in a solvent) onto the substrate layer 202, and the deposited solution or hardcoat liquid is then cured using ultra-violet radiation and/or a thermal method.

The first wet hardcoat layer 205 is deposited on a first side 221 of the substrate layer 202, and the second wet hardcoat layer 204 is deposited on a second side 222 of the substrate layer 202. In one or more embodiments, the first wet hardcoat layer 205 is deposited on a first outer surface of the substrate layer 202 on the first side 221, and the second wet hardcoat layer 204 is deposited on a second outer surface of the substrate layer 202 on the second side 222.

A dry deposition process may include chemical vapor deposition (CVD), plasma enhanced chemical vapor deposition (PECVD), atomic layer deposition (ALD), physical vapor deposition (PVD), thermal evaporation, electron beam evaporation, and/or other deposition techniques. The dry deposition process may optionally be enhanced with a plasma, and may be processed in sheet-to-sheet equipment or roll-to-roll equipment. The dry deposition process can be performed in sufficiently equipped sheet processing equipment in which a carrier glass sheet is loaded with the substrate layer 202 including the first wet hardcoat layer 205 and the second wet hardcoat layer 204 deposited thereon in a dual-sided configuration. The substrate layer 202 may be directly loaded on to the carrier glass sheet or bonded to slimmed or ultra-thin glass substrate which in-turn may be loaded on the carrier for dry deposition processing.

In the implementation of FIG. 2A, the one or more adhesion promotion layers 206 are deposited on the second wet hardcoat layer 204. The one or more adhesion promotion layers 206 can be hardcoat layers deposited using a dry deposition process. The dry hardcoat layer 208, which is deposited using a dry deposition process, is deposited on the adhesion promotion layer 206. The second wet hardcoat layer 204, the adhesion promotion layer 206, and the dry hardcoat layer 208 form a multi-layer hardcoat 212. An anti-smudge layer 210 is deposited on the dry hardcoat layer 208. The anti-smudge layer 210 may be an anti-fingerprint layer. The anti-smudge layer 210 may be deposited using a dry deposition process or a wet deposition process.

In the implementation of FIG. 2B, the flexible cover lens film 220 includes the adhesion promotion layer 206 deposited on the substrate layer 202. The adhesion promotion layer 206 may be deposited using a dry vacuum deposition process, such as CVD, PECVD, ALD, PVD, thermal evaporation, electron beam evaporation, and/or other dry deposition process(es), or using a wet deposition process. The dry hardcoat layer 208, which is deposited using a dry deposition process, is deposited on the adhesion promotion layer 206. The second wet hardcoat layer 204, which is deposited using a wet deposition process, is deposited on the dry hardcoat layer 208. In one or more embodiments, the second wet hardcoat layer 204 includes an anti-smudge or anti-fingerprint additive, and/or an anti-smudge layer is not deposited on the second wet hardcoat layer 204. In one or more embodiments, an anti-smudge layer (such as the anti-smudge layer 210 shown in FIG. 2B) is deposited on the second wet hardcoat layer 204, and the anti-smudge layer may be deposited using a dry deposition process or a wet deposition process. The second wet hardcoat layer 204, the adhesion promotion layer 206, and the dry hardcoat layer 208 form a multi-layer hardcoat 212.

In the implementation of FIG. 2C, the flexible cover lens film 230 includes the adhesion promotion layer 206 deposited on the substrate layer 202. The second wet hardcoat layer 204, which is deposited using a wet deposition process, is deposited on the adhesion promotion layer 206. The dry hardcoat layer 208, which is deposited using a dry deposition process, is deposited on the second wet hardcoat layer 204. The second wet hardcoat layer 204, the adhesion promotion layer 206, and the dry hardcoat layer 208 form a multi-layer hardcoat 212. An anti-smudge layer 210 is deposited on the dry hardcoat layer 208. The anti-smudge layer 210 may be deposited using a dry deposition process or a wet deposition process.

In the implementation of FIG. 2D, the flexible cover lens film 240 includes a first adhesion promotion layer 206a deposited on the substrate layer 202. The second wet hardcoat layer 204, which is deposited using a wet deposition process, is deposited on the first adhesion promotion layer 206a. A second adhesion promotion layer 206b is deposited on the second wet hardcoat layer 204. The dry hardcoat layer 208, which is deposited using a dry deposition process, is deposited on the second adhesion promotion layer 206b. The first adhesion promotion layer 206a, the second wet hardcoat layer 204, the second adhesion promotion layer 206b, and the dry hardcoat layer 208 form a multi-layer hardcoat 212. An anti-smudge layer 210 is deposited on the dry hardcoat layer 208. The anti-smudge layer 210 may be deposited using a dry deposition process or a wet deposition process.

In the implementation of FIG. 2E, the flexible cover lens film 250 includes the first adhesion promotion layer 206a deposited on the substrate layer 202. The dry hardcoat layer 208, which is deposited using the dry deposition process, is deposited on the first adhesion promotion layer 206a. The second adhesion promotion layer 206b is deposited on the dry hardcoat layer 208. The second wet hardcoat layer 204, which is deposited using the wet deposition process, is deposited on the second adhesion promotion layer 206b. In one or more embodiments, the second wet hardcoat layer 204 includes an anti-smudge additive. In one or more embodiments, an anti-smudge layer is deposited on the second wet hardcoat layer 204, and the anti-smudge layer may be deposited using a dry deposition process or a wet deposition process. The first adhesion promotion layer 206a, the dry hardcoat layer 208, the second adhesion promotion layer 206b, and the second wet hardcoat layer 204 form a multi-layer hardcoat 212.

The flexible cover lens films 200, 220, 230, 240, 250 of FIGS. 2A-2E have a pencil hardness of 3H to 9H, a total transmission greater than 88% (such as 90% or higher), a haze of about 1% or less (such as less than 1%), and a yellowness index of b*<1. In one or more embodiments, the flexible cover lens films 200, 220, 230, 240, 250 have a pencil hardness of 9H, a total transmission greater than 92%, and a haze of 0.5% or less. The flexible cover lens films 200, 220, 230, 240, 250 have flexibility over repeated cycles to bend to up to 1 mm inside-radius of curvature or up to 2 mm out-side radius of curvature. The flexible cover lens films 200, 220, 230, 240, 250 have a scratch resistance as measured by a standard steel wool test loaded up to 1 kg and able to withstand a large number of cycles, for example 2000 cycles. The change in haze of the flexible cover lens films 200, 220, 230, 240, 250 after a steel wool abrasion test is less than 1%, demonstrating that the flexible cover lens films 200, 220, 230, 240, 250 each can have a high abrasion resistance. The flexible cover lens films 200, 220, 230, 240, 250 have an abrasion resistance as measured by a Taber abrasion resistance test loaded up to 1 kg and able to withstand a large number of cycles, for example 100 cycles. The change in haze of the flexible cover lens films 200, 220, 230, 240, 250 after a Taber abrasion resistance test is less than 2%.

In FIGS. 2A-2E, the first wet hardcoat layer 205 and the second wet hardcoat layer 204 may each be deposited using a roll to roll solution processing method. The dry hardcoat layer 208 may be deposited using CVD, PVD, PECVD, or ALD. In one or more embodiments, the dry hardcoat layer 208 is deposited using CVD or PVD. The multi-layer hardcoat 212 may have a thickness T1 of 1 μm to 30 μm. In one or more embodiments, the thickness T1 is 5 μm to 10 μm.

In FIGS. 2A-2E, the first wet hardcoat layer 205 and/or the second wet hardcoat layer 204 may include one or more of: urethane acrylate(s), polyester resin, polyester acrylate, epoxy acrylate, urethane, epoxy-polycarbonate, cellulose, acetal, polyethylene, polystyrene, polyamide, polyimide, melamine, phenol, silicone, solgel-siloxane hybrid(s), silica nanoparticles, and/or a combination thereof. Hybrid siloxanes may include organic and inorganic elements, including metal alkoxides. The second wet hardcoat layer 204, which is deposited using a wet deposition process, may further include one or more of: radiation curable acrylate(s), aliphatic urethane acrylate(s), copolymer(s) thereof, elastomer(s) thereof, and/or a combination thereof. The first wet hardcoat layer 205 and the second wet hardcoat layer 204 may each have a thickness T2 of about 0.5 μm to about 40 μm. The first wet hardcoat layer 205 and the second wet hardcoat layer 204 may each have a refractive index of about 1.430 to about 1.150, an optical transmission of about 85% to about 98%, and a pencil hardness of about 2H to about 9H. The first wet hardcoat layer 205 and the second wet hardcoat layer 204 may each have a nano-indentation hardness of about 0.5 GPa to about 1.5 GPa, and/or an elastic modulus raging from about 5 Gpa to about 13 GPa as measured by nano-indentation.

The wet deposition processes for depositing the first wet hardcoat layer 205 and the second wet hardcoat layer 204 may each include applying a chemistry solution (e.g., a hardcoat liquid) using spray nozzles and/or various Mayer rods, heating in a non-active convection oven between 75° C. and 85° C. for between 100 seconds and 140 seconds (e.g., before, during, and/or after application), and/or irradiating with a UV lamp (e.g., curing) for between 100 seconds and 140 seconds at between 300 mJ/cm² and 500 mJ/cm². The solution of the wet deposition process may be processed in an ion atmosphere by bar coating, slot-die coating, comma coating, micro gravure coating, spin coating, gravure coating, and/or cast coating. In one or more embodiments, the deposited solution of the wet deposition process is cured using ultraviolet radiation. In one or more embodiments, the deposited solution of the wet deposition process is cured using an electron beam processing. In one or more embodiments, the deposited solution of the wet deposition process is cured using a thermal process.

The dry hardcoat layer 208 may include one or more of: oxide(s) and/or nitride(s) of silicon, silicon oxycarbide(s) (SiCₓO_{y}), silicon oxynitride(s), and/or silicon carbide(s) (SiC). The dry hardcoat layer 208 may have a thickness T3 of about 0.05 μm to about 30 μm. Precursors used in the dry deposition process may include organic polymer precursor(s) (liquid or gas) with carbon, such as one or more of hexamethyldisiloxane (HMDSO), plasmapolymerized HMDSO (ppHMDSO), tetramethyl cyclotetrasiloxane (TOMCAT), hexamethyldisilazane (HMDSN), and/or tetraethyl orthosilicate (TEOS). Precursors used in the dry deposition process may include sputtering various silica and/or quartz material(s) to deposit various carbon-mixed oxide(s) and/or nitride(s) of silicon or precursor(s) without carbon present, such as silane (SiH4).

The dry hardcoat layer 208 may have a refractive index of about 1.450 to about 1.150, an optical transmission of about 85% to about 98%, and a pencil hardness of about 2H to about 9H. The dry hardcoat layer 208 may have a nano-indentation hardness of about 1 GPa to about 8 GPa, and/or an elastic modulus raging from about 5 Gpa to about 70 GPa as measured by nano-indentation. The dry hardcoat layer 208 may have a high hardness controlled by the oxidizers or initiators to precursor ratio, such as oxygen (O₂), nitrous oxide (N₂O), tert-butyl peroxide (TBPO), and/oor acrylate monomers, particularly ethyl-hexyl acrylate, and/or cross linking agents such as butanediol-diacrylate (BDDA) to minimize the carbon present in the dry hardcoat layer 208.

The substrate layer 202 of FIGS. 2A-2E has a thickness T4 of 2 μm to 100 μm. The substrate layer 202 is formed of one or more polymeric materials. The substrate layer 202 includes one or more of: polyethylene terephthalate (PET), triacetylcellulose, polycarbonate, polyamides, polymethacrylic acid methylesther, cycloolefin polymer, polyethylene napthalene (PEN), and/or colorless polyimides (CPI). In one or more embodiments, the thickness T4 of the substrate layer 202 is about 25 μm to 50 μm, and is a CPI layer. The anti-smudge layer 210 can be an oleophobic film. The anti-smudge layer 210 may be a perfluoropolyether (PFPE) based silane polymer molecule (e.g., including various chlorosilanes, oxysilanes, and/or fluoroethylenes, etc.) covalently bonded to the surface of the layer below the anti-smudge layer 210. The anti-smudge layer 210 may be wet or vacuum-dry coated. The anti-smudge layer 210 may have a thickness of 3 nm to 150 nm, such as about 50 nm to about 70 nm.

The one or more adhesion promotion layers 206 may have a thickness of 50 nm to 1500 nm. The one or more adhesion promotion layers 206 may be deposited using a dry deposition process, and may include oxide(s) and/or nitride(s) of silicon, silicon oxycarbide(s), and/or silicon oxynitride(s). Precursors used in the dry deposition process may include organic polymer precursor(s) (liquid or gas) with carbon, such as one or more of HMDSO, ppHMDSO, TOMCAT, HMDSN, and/or TEOS. Precursors used in the dry deposition process may include sputtering various silica and/or quartz material(s) to deposit various carbon-mixed oxide(s) and/or nitride(s) of silicon.

The one or more adhesion promotion layers 206 may be deposited in a wet deposition process, and may include one or more polymeric and/or oligomeric materials, such as acrylate, silicone, and/or optically clear adhesive(s) (OCA). In one or more embodiments, the one or more adhesion promotion layers 206 deposited using a wet deposition process may be formed from a liquid optically clear adhesive (LOCA) that can be dispensed in various ways (e.g., spray nozzles, Mayer rods, slot dies, gravure heads, and/or bar coaters, etc.) and cured by UV exposure, or by heat, and/or can be moisture and/or pressure sensitive and/or be cured by adjusting or controlling the moisture and/or pressure.

Each of the one or more adhesion promotion layers 206 may have a refractive index of about 1.430 to about 1.150, and an optical transmission of about 85% to about 98%. Each of the one or more adhesion promotion layers 206 may have a nano-indentation hardness of about 0.4 GPa to about 5 GPa, and/or an elastic modulus ranging from about 2.5 Gpa to about 70 GPa as measured by nano-indentation. Each of the one or more adhesion promotion layers 206 may have a relatively high hardness controlled by the oxidizers or initiators to precursor ratio, such as O₂, N₂O, TBPO, and/or acrylate monomer(s), such as ethyl-hexyl acrylate, and/or cross linking agents such as BDDA to accurately control the carbon present.

One or more of the flexible cover lens films 200, 220, 230, 240, 250 may be stacked on each other. For example, the flexible cover lens film 200 may be stacked on the flexible cover lens film 220, or the flexible cover lens film 200 may double such that there are two flexible cover lens films 200. The multi-layer hardcoat 212 may be stacked one or more times on the substrate layer 202. The first wet hardcoat layer 205 may be stacked one or more times under the substrate layer 202. The one or more flexible cover lens films 200, 220, 230, 240, 250, the stacked first wet hardcoat layers 205, and/or the stacked multi-layer hardcoats 212 may be independently be adhered, bonded, or otherwise held together by one or more adhesives, such as with one or more OCAs. The one or more flexible cover lens films 200, 220, 230, 240, 250, the stacked first wet hardcoat layers 205, and/or stacked multi-layer hardcoats 212 may be independently be adhered, bonded, or otherwise held together without the use of adhesives.

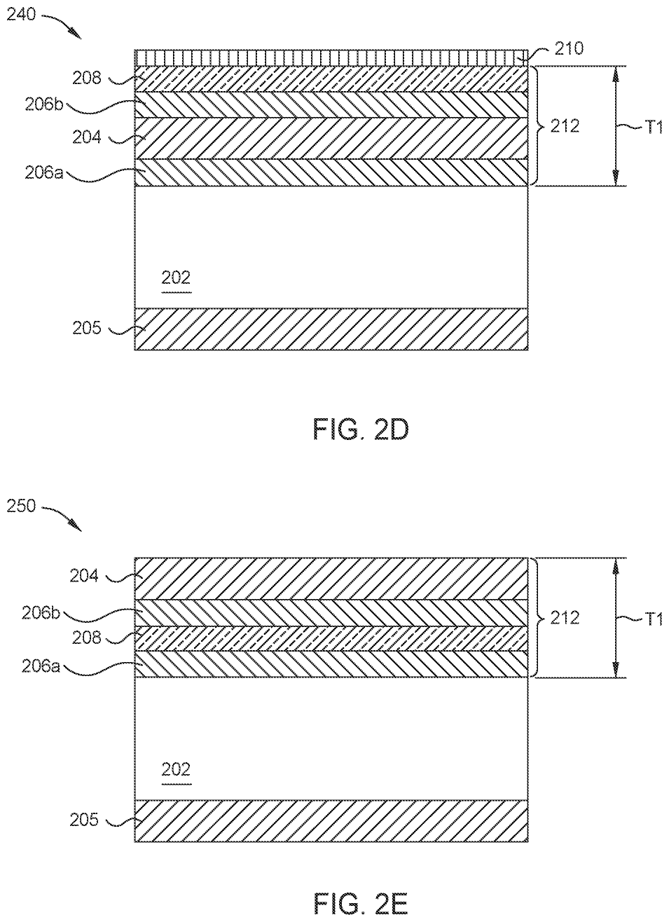

FIG. 3 is a schematic cross-sectional view of an exemplary embodiment of a flexible cover lens film 300 including a double-stacked multi-layer hardcoat of the flexible cover lens film 200 and a double-stacked first wet hardcoat layer 205, according to one or more embodiments. In the flexible cover lens film 300, a first multi-layer hardcoat 212a is disposed on the second side of the substrate layer 202 and a second multi-layer hardcoat 212b is disposed on the first multi-layer hardcoat 212a. Two first wet hardcoat layers 205a, 205b are disposed on the first side of the substrate layer 202. One or more adhesive layers 306 are disposed between the first multi-layer hardcoat 212a and the second multi-layer hardcoat 212b. The one or more adhesive layers 306 may be sacrificial adhesive layers. The one or more adhesive layers 306 may be the one or more adhesion promotion layers 206 of FIGS. 2A-2E. Both the first and second multi-layer hardcoat 212a, 212b include the second wet hardcoat layer 204, the adhesive promotion layer 206 disposed on the second wet hardcoat layer 204, and the dry hardcoat layer 208 disposed on the adhesive promotion layer 206. The anti-smudge layer 210 (as shown in FIG. 3) may be deposited on the second multi-layer hardcoat 212b. The present disclosure contemplates that the anti-smudge layer 210 may be omitted.

If it is desirable to remove and replace the top-most flexible cover lens films (e.g., due to being scratched or suffering other damage), such as the second multi-layer hardcoat 212b of FIG. 3, the one or more adhesive layers, such as the adhesive layer 306, can be selectively degraded, destroyed, or otherwise removed in order to separate the top cover lens (e.g. the second multi-layer hardcoat 212b of FIG. 3) from the bottom cover lens film (e.g., the first multi-layer hardcoat 212a of FIG. 3). The adhesives (e.g., the adhesive layers 306 of FIG. 3) bonding the two stacks of cover films can be degraded at a predetermined temperature, a predetermined wavelength and/or dosage of ultraviolet (UV) light, and/or a predetermined mechanical removal mechanism.

In one or more embodiments, the sacrificial adhesives (e.g., the adhesive layers 306 of FIG. 3) bonding two stacked flexible cover lens films (e.g., the first and second multi-layer hardcoat 212a, 212b of FIG. 3) may be degradable at a predetermined temperature. For example, the adhesives may be degradable at a temperature of about 80° C., about 90° C., or about 100° C. to about 120° C. In one or more embodiments, the sacrificial adhesives are degradable when exposed to UV light at a predetermined wavelength and/or predetermined dosage. For example, the adhesives are degradable when exposed to UV light having a wavelength of about 350 nm to about 375 nm, such as about 365 nm. The adhesives may be degraded by exposing the adhesive to the UV light for a period of about 0.5 seconds, about 1 second, or about 5 seconds to about 30 seconds, about 60 seconds, or about 90 seconds.

A method of forming the flexible cover lens films 200, 220, 230, 240, 250 may include positioning the substrate layer 202 and depositing the multi-layer hardcoat 212 on the substrate layer 202. The layers 204-208 of the multi-layer hardcoat 212 may be deposited using both wet and dry deposition processes, such as CVD, PVD, ambient (e.g., atmospheric) solution processing methods in sheet-to-sheet processing equipment, and/or roll-to-roll equipment. It is contemplated that additional layers may be present in the flexible cover lens films 200, 220, 230, 240, 250, such as additional adhesion promotion layers or impact resistance layers. The cover lens films described herein may be used in any display device.

Combining wet and dry deposition processes to form the multi-layer hardcoat facilitates an optically clear, high hardness, and bendable cover lens film. The combination of dry films and wet films facilitates enhancing anti-abrasion properties and elasticity of the cover lens film while allowing for an anti-smudge layer to be deposited on top of the multi-layer hardcoat. By combining wet and dry deposition processes to form the multi-layer hardcoat, the cover lens films have facilitated elasticity, strength, optical transmission, wear resistance, anti-abrasion properties, and thermostability.

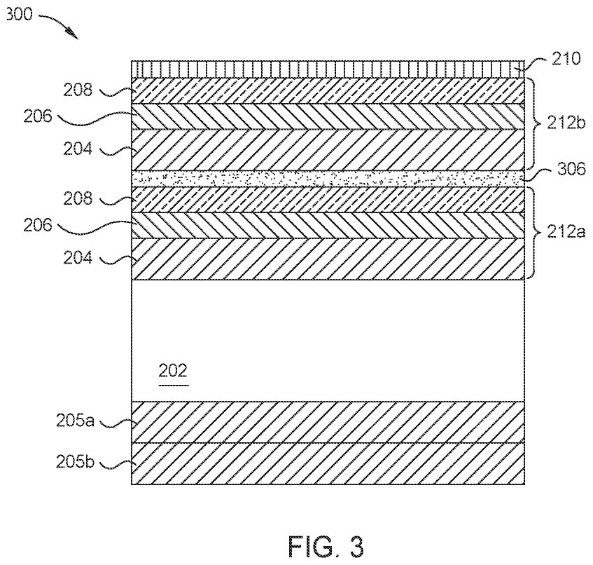

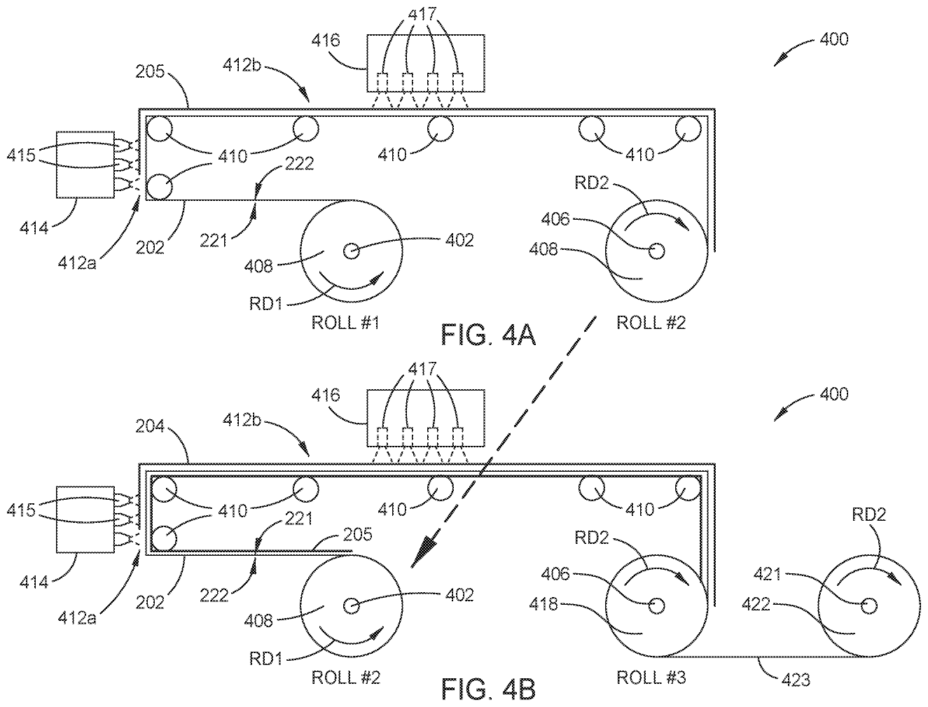

FIG. 4A is a schematic plan view of a coating system 400 during a first wet deposition process, according to one or more embodiments.

The coating system 400 includes a first rotatable stem 402 configured to receive a first storage reel 404, a second rotatable stem 406 configured to receive a second storage reel 408, and a plurality of transfer rollers 410. The transfer rollers 410 are disposed along a transfer path between the first storage reel 404 and the second storage reel 408. The coating system 400 includes a coating module 414 interfacing with a first section 412a of the transfer path, and the coating module 414 includes a bar, a slot die, one or more comma rollers, a micro-gravure, a gravure, one or more cast nozzles, one or more cast rollers, and/or a plurality of spray nozzles 415. The present disclosure contemplates that one or more spray nozzles 415 may be used. The coating system 400 includes a curing module 416 interfacing with a second section 412b of the transfer path. The curing module 416 includes one or more ultraviolet (UV) light sources 417. The present disclosure contemplates that other energy sources (such as microwave sources, heat sources, and/or electron beam sources) may be used in place of the UV light sources 417.

The first storage reel 404 is mounted to the first rotatable stem 402, and the second storage reel 408 is mounted to the second rotatable stem 406. The substrate layer 202 is coiled on the first storage reel 404. During the first wet deposition process, the first rotatable stem 402 is driven to rotate the first storage reel 404 in a first rotational direction RD1, and the second rotatable stem 406 is driven to rotate the second storage reel 408 in a second rotational direction RD2. The substrate layer 202 is transferred from the first storage reel 404 and to the second storage reel 408. During the transferring, the coating module 414 coats (e.g., sprays or rolls, for example) a liquid hardcoat onto the first side 221 of the substrate layer 202 to form the first wet hardcoat layer 205. The second side 222 rolls over the transfer rollers 410 during the transfer. During the transferring, the UV light sources 417 direct energy (e.g., UV light) toward the first wet hardcoat layer 205 to cure the first wet hardcoat layer 205.

Rotating the first storage reel 404 in the first rotational direction RD1, and rotating the second storage reel 408 in the second rotational direction RD2 that is opposite of the first rotational direction RD1, reels the substrate layer 202 and the first wet hardcoat layer 205 onto the second storage reel 408 such that the first side 221 and the second side 222 flip (see FIG. 4B).

FIG. 4B is a schematic plan view of the coating system 400 during a second wet deposition process, according to one or more embodiments.

Between the first wet deposition process of FIG. 4A and the second wet deposition process of FIG. 4B, locations of the first storage reel 404 and the second storage reel 408 are altered. In one or more embodiments, the second storage reel 408 is positioned in place of the first storage reel 404 (e.g., mounted to the first rotatable stem 402) for the second wet deposition process. In one or more embodiments, a third storage reel 418 is mounted to the second rotatable stem 406. In one or more embodiments, the positions of the first storage reel 404 and the second storage reel 408 are swapped such that second storage reel 408 is mounted to the first rotatable stem 402 and the first storage reel 404 is mounted to the second rotatable stem 406.

The first side 221 and the second side 222 are flipped such that the second side 222 faces the coating module 414, and the first side 221 and the first wet hardcoat layer 205 face the transfer rollers 410. During the second wet deposition process, the second storage reel 408 is rotated in the first rotational direction RD1, and the third storage reel 418 is rotated in the second rotational direction RD2.

The substrate layer 202 and the first wet hardcoat layer 205 are transferred from the second storage reel 408 and to the third storage reel 418. During the transferring, the coating module 414 coats (e.g, sprays or rolls, for example) the liquid hardcoat onto the second side 222 of the substrate layer 202 to form the second wet hardcoat layer 204. The first wet hardcoat layer 205 rolls over the transfer rollers 410 during the transfer. During the transferring, the UV light sources 417 direct energy (e.g., UV light) toward the second wet hardcoat layer 204 to cure the second wet hardcoat layer 204. Simultaneously with the rotation of the third storage reel 418, a third rotatable stem 421 is driven to rotate a fourth storage reel 422 (in the second rotational direction RD2) to transfer a protective film 423 from the fourth storage reel 422 and to the third storage reel 418. The protective film 423 being reeled onto the third storage reel 418 is deposited on the cured second wet hardcoat layer 204. The protective film 423 is deposited between the second wet hardcoat layer 204 and the first wet hardcoat layer 205.

The present disclosure contemplates that other deposition equipment can be used in place of the coating module 414. In one or more embodiments, a first hardcoat roller can roll the liquid adhesive on the first side 221 to form the first wet hardcoat layer 205, and a second hardcoat roller can simultaneously roll the liquid adhesive on the second side 222 to form the second wet hardcoat layer 204

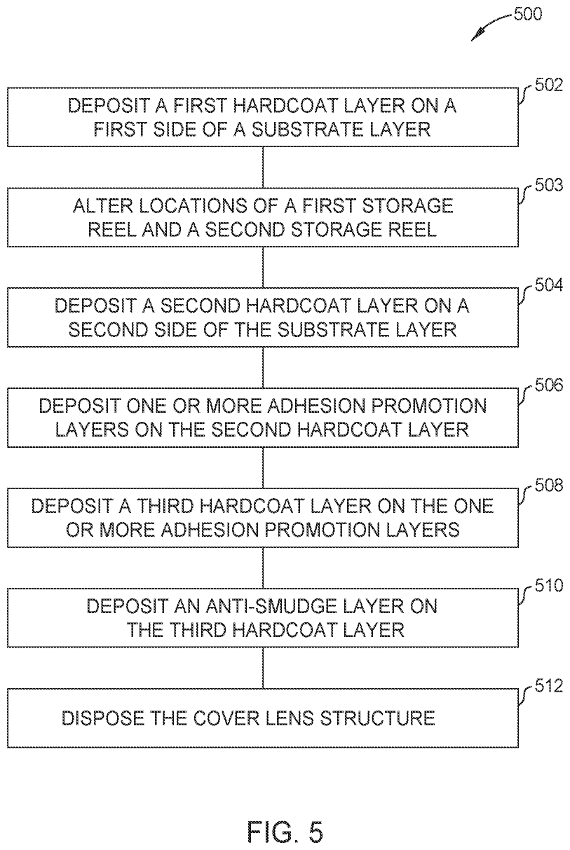

FIG. 5 is a schematic block diagram view of a method 500 of forming a cover lens structure, according to one or more embodiments.

Operation 502 includes depositing a first hardcoat layer on a first side of a substrate layer using a first wet deposition process. The substrate layer is a polymeric layer. In one or more embodiments, the substrate layer is formed of one or more of polyethylene terephthalate (PET), polyethylene naphthalate (PEN), cellulose triacetate (TAC), polyimide (PI), and/or colorless polyimide (CPI). The present disclosure contemplates that other polymeric materials may be used for the substrate layer. In one or more embodiments, the depositing of the first hardcoat layer includes coating a hardcoat liquid on the first side, and curing the hardcoat liquid on the first side. In one or more embodiments, the depositing of the first hardcoat layer includes rotating a first storage reel in a first rotational direction, and rotating a second storage reel in a second rotational direction that is opposite of the first rotational direction to transfer the substrate layer from the first storage reel to the second storage reel. In one or more embodiments, the transferring of the substrate layer from the first storage reel to the second storage reel includes moving the substrate layer over a plurality of transfer rollers disposed along a transfer path between the first storage reel and the second storage reel.

Operation 503 includes altering locations of the first storage reel and the second storage reel. In one or more embodiments, the altering includes swapping the positions of the first storage reel and the second storage reel. In one or more embodiments, the altering includes positioning the second storage reel in place of the first storage reel, and positioning a third storage reel in place of the second storage reel.

Operation 504 includes depositing a second hardcoat layer on a second side of the substrate layer using a second wet deposition process. In one or more embodiments, the depositing of the second hardcoat layer includes coating the hardcoat liquid on the second side, and curing the hardcoat liquid on the second side. In one or more embodiments, the depositing of the second hardcoat layer includes rotating the second storage reel in the first rotational direction, and rotating a third storage reel in the second rotational direction that is opposite of the first rotational direction to transfer the substrate layer from the second storage reel to the third storage reel. In one or more embodiments the method 500 includes, while rotating the third storage reel, rotating a fourth storage reel in the second rotational direction to transfer a barrier film from the fourth storage reel to the third storage reel, and deposit the barrier film between the first hardcoat layer and the second hardcoat layer.

The first wet deposition process of operation 502 and the second wet deposition process of operation 504 each deposit the first and second hardcoat layer using roll-to-roll equipment (such as the transfer rollers 410 and the storage reels 404, 408, 418, 422 shown in FIGS. 4A and 4B).

Operation 506 includes depositing one or more adhesion promotion layers. In one or more embodiments, the one or more adhesion promotion layers are deposited on the second hardcoat layer.

Operation 508 includes depositing a third hardcoat layer using a dry deposition process. In one or more embodiments, the third hardcoat layer is deposited on the one or more adhesion promotion layers.

Operation 510 includes depositing an anti-smudge layer. In one or more embodiments, the anti-smudge layer is deposited on the third hardcoat layer.

The first hardcoat layer and the second hardcoat layer are each deposited at a roll temperature that is less than 58 degrees Celsius. In one or more embodiments, the roll temperature is an ambient temperature, for example a room temperature.

Operation 512 includes disposing the cover lens structure to position the first hardcoat layer above a touch panel and a display structure of a display device.

Benefits of the present disclosure include strong mechanical properties (such as hardness and impact resistance), abrasion resistance, flexibility, elasticity, optical transmission, and/or wear resistance. Benefits of the present disclosure also include low hazing, low oligomer migration (such as within and from the substrate layer 202), and/or low yellow indices. As an example, the present disclosure facilitates lower oligomer migration in and from the substrate layer, lower hazing, lower yellow indices, and enhanced optical transmission (and optical device performance) at relatively strong mechanical properties.

It is contemplated that aspects described herein can be combined. For example, one or more features, aspects, components, operations, and/or properties of the flexible cover lens films 200, 220, 230, 240, 250, and/or 300, the display device 100, the coating system 400, the first wet deposition process shown in FIG. 4A, the second wet deposition process shown in FIG. 4B, and/or the method 500 can be combined. It is further contemplated that combination(s) can achieve the aforementioned benefits.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges may appear in one or more claims below.

What is claimed is:

1. A cover lens structure for display devices, comprising:
a substrate layer comprising a first side and a second side;
a first wet hardcoat layer deposited on the first side of the substrate layer;
a second wet hardcoat layer deposited on the second side of the substrate layer;
one or more adhesion promotion layers formed above the second side of the substrate layer; and
a dry hardcoat layer formed above the second side of the substrate layer.

2. The cover lens structure of claim 1, further comprising:
an anti-smudge layer formed above the dry hardcoat layer, wherein the one or more adhesion promotion layers are formed above the first wet hardcoat layer, and the dry hardcoat layer is formed above the one or more adhesion promotion layers.

3. The cover lens structure of claim 1, wherein the substrate layer is formed of one or more polymeric materials.

4. The cover lens structure of claim 3, wherein the substrate layer is formed of polyethylene terephthalate (PET).

5. The cover lens structure of claim 3, wherein the first wet hardcoat layer and the second wet hardcoat layer each comprises one or more of: one or more urethane acrylates, polyester resin, polyester acrylate, epoxy acrylate, urethane, epoxy-polycarbonate, cellulose, acetal, polyethylene, polystyrene, polyamide, polyimide, melamine, phenol, silicone, one or more solgel-siloxane hybrids, or silica nanoparticles.

6. The cover lens structure of claim 3, wherein the dry hardcoat layer comprises one or more of: one or more silicon oxides, one or more silicon nitrides, one or more silicon oxycarbides, one or more silicon oxynitrides, or one or more silicon carbides.

7. A method of forming a cover lens structure, comprising:
depositing a first hardcoat layer on a first side of a substrate layer using a first wet deposition process;
depositing a second hardcoat layer on a second side of the substrate layer using a second wet deposition process;
depositing one or more adhesion promotion layers above the second side;
depositing a third hardcoat layer above the second side using a dry deposition process;
depositing an anti-smudge layer above the second side; and
disposing the cover lens structure to position the first hardcoat layer above a touch panel and a display structure of a display device.

8. The method of claim 7, wherein the first hardcoat layer and the second hardcoat layer are each deposited at a roll temperature that is less than 58 degrees Celsius, the one or more adhesion promotion layers are deposited on the second hardcoat layer, the third hardcoat layer is deposited on the one or more adhesion promotion layers, and the anti-smudge layer is deposited on the third hardcoat layer.

9. The method of claim 7, wherein the substrate layer is formed of one or more polymeric materials.

10. The method of claim 9, wherein the substrate layer is formed of polyethylene terephthalate (PET).

11. The method of claim 7, wherein the depositing of the first hardcoat layer and the depositing of the second hardcoat layer each comprises:
spraying a hardcoat liquid on the respective first side or second side; and
curing the hardcoat liquid on the respective first side or second side.

12. The method of claim 11, wherein the depositing of the first hardcoat layer further comprises:
rotating a first storage reel in a first rotational direction; and
rotating a second storage reel in a second rotational direction that is opposite of the first rotational direction to transfer the substrate layer from the first storage reel to the second storage reel.

13. The method of claim 12, wherein the transferring of the substrate layer from the first storage reel to the second storage reel comprises:
moving the substrate layer over a plurality of transfer rollers disposed along a transfer path between the first storage reel and the second storage reel.

14. The method of claim 12, further comprising altering locations of the first storage reel and the second storage reel.

15. The method of claim 14, wherein the depositing of the second hardcoat layer further comprises:
rotating the second storage reel in the first rotational direction; and
rotating a third storage reel in the second rotational direction to transfer the substrate layer from the second storage reel to the third storage reel.

16. The method of claim 15, further comprising, while rotating the third storage reel:
rotating a fourth storage reel in the second rotational direction to transfer a barrier film from the fourth storage reel to the third storage reel, and deposit the barrier film between the first hardcoat layer and the second hardcoat layer.

17. A coating system, comprising:
a first rotatable stem configured to receive a first storage reel;
a second rotatable stem configured to receive a second storage reel;
a plurality of transfer rollers disposed along a transfer path between the first storage reel and the second storage reel;
a coating module interfacing with a first section of the transfer path, the coating module comprising one or more of: a bar, a slot die, one or more comma rollers, a micro-gravure, a gravure, one or more cast nozzles, one or more cast rollers, or one or more spray nozzles; and
a curing module interfacing with a second section of the transfer path.

18. The coating system of claim 17, wherein the curing module comprises one or more ultraviolet (UV) light sources.

19. The coating system of claim 17, wherein the first storage reel is mounted to the first rotatable stem, the second storage reel is mounted to the second rotatable stem, and a substrate layer is coiled on the first storage reel.

20. The coating system of claim 19, wherein the substrate layer is formed of one or more polymeric materials.
